(19) United States
(12) Patent Application Publication
(10) Pub. No.: US 2024/0258250 A1
(43) Pub. Date: Aug. 1, 2024

(54) SEMICONDUCTOR STRUCTURE FOR 3D MEMORY AND MANUFACTURING METHOD THEREOF

(71) Applicant: MACRONIX International Co., Ltd., Hsinchu (TW)

(72) Inventor: Yu-Tang Lin, Taipei City (TW)

(73) Assignee: MACRONIX International Co., Ltd., Hsinchu (TW)

(21) Appl. No.: 18/162,718

(22) Filed: Feb. 1, 2023

(51) Int. Cl. H01L 23/60; H10B 99/00

(52) U.S. Cl. CPC H01L 23/60; H10B 99/00

(57) ABSTRACT

Provided are a semiconductor structure for a three-dimensional (3D) memory and a manufacturing method thereof. The semiconductor structure may be used in a 3D AND flash memory. The semiconductor structure includes a dielectric layer disposed on a substrate, a ground layer, a ground via, a dielectric stacked structure, and a through via. The ground layer is disposed on the dielectric layer. The ground via is disposed in the ground layer and the dielectric layer and electrically connected to the substrate. The dielectric stacked structure is disposed on the ground layer. The through via is disposed in the dielectric stacked structure and connected to the ground layer. The dielectric stacked structure has a vertical channel hole.

### BACKGROUND

### Technical Field

The present invention relates to a semiconductor device and a manufacturing method thereof, and particularly to a semiconductor structure for three-dimensional (3D) memory and a manufacturing method thereof.

### Description of Related Art

A non-volatile memory, such as a flash memory, has the advantage that the stored data will not disappear after power off, so it has become a kind of memory widely used in personal computers and other electronic apparatuses.

In the current 3D flash memory, in the memory array region, the vertical channel (VC) is disposed in the stacked structure composed dielectric layers and conductive layers as gates. Generally speaking, during forming the vertical channel, a patterned hard mask layer with considerable thickness is formed on a stacked structure composed of oxide layers and nitride layers, the patterning process is performed to form a vertical channel hole, and a channel material is filled in the vertical channel hole.

However, since the patterned hard mask layer usually needs to have a large thickness, the thickness uniformity of the patterned hard mask layer is reduced. In particular, since the edge of the substrate usually has a beveled profile, the stacked structure has a beveled sidewall at the edge of the substrate. In this way, when the patterned hard mask layer is extended to the sidewall of the stacked structure, the patterned hard mask layer on the sidewall of the stacked structure may have a thinner thickness. In the subsequent deep-etching process for forming the vertical channel hole, charges may gradually accumulate around the vertical channel hole and at the thinner portion of the patterned hard mask layer. When the accumulated charges are too much, the arcing occur, causing damage to the substrate and/or the device disposed on the substrate.

### SUMMARY

The present invention provides a semiconductor structure for a 3D memory, in which the through via is disposed in the dielectric stacked structure and connected to the ground layer to release the charges generated in the process.

The present invention provides a manufacturing method of a semiconductor structure for the 3D memory, in which the through via is formed in the dielectric stacked structure and connected to the ground layer.

The semiconductor structure for a 3D memory of the present invention includes a dielectric layer, a ground layer, a ground via, a dielectric stacked structure, and a through via. The dielectric layer is disposed on a substrate. The ground layer is disposed on the dielectric layer. The ground via is disposed in the ground layer and the dielectric layer, and electrically connected to the substrate. The dielectric stacked structure is disposed on the ground layer. The through via is disposed in the dielectric stacked structure, and connected to the ground layer. The dielectric stacked structure has a vertical channel hole.

In an embodiment of the semiconductor structure of the present invention, a material of the through via includes polysilicon or metal.

In an embodiment of the semiconductor structure of the present invention, an aperture of the through via is the same as an aperture of the vertical channel hole.

In an embodiment of the semiconductor structure of the present invention, a shortest distance between the through via and the vertical channel hole is 10% or more of an aperture of the vertical channel hole.

In an embodiment of the semiconductor structure of the present invention, a shortest distance between the through via and the ground via is 10% or more of an aperture of the ground via.

In an embodiment of the semiconductor structure of the present invention, a bottom surface of the through via is located on a top surface of the ground layer.

In an embodiment of the semiconductor structure of the present invention, a bottom surface of the through via is located in the ground layer.

In an embodiment of the semiconductor structure of the present invention, a bottom surface of the through via is located on a top surface of the dielectric layer.

In an embodiment of the semiconductor structure of the present invention, a bottom surface of the through via is located at the same level as a bottom surface of the vertical channel hole.

In an embodiment of the semiconductor structure of the present invention, the semiconductor structure further includes a device structure layer disposed between the substrate and the dielectric layer, wherein the ground via is electrically connected to the substrate through the device structure layer.

In an embodiment of the semiconductor structure of the present invention, the semiconductor structure further includes a device structure layer, wherein the substrate includes a memory region, a periphery region, an edge region and a peripheral device region, the periphery region is located between the memory region and the edge region, the peripheral device region is adjacent to the memory region, and the device structure layer is disposed on the substrate in the peripheral device region.

In an embodiment of the semiconductor structure of the present invention, the substrate includes a memory region, a periphery region and a peripheral device region, the periphery region is located between the memory region and the edge region, and the through via is located in the periphery region.

In an embodiment of the semiconductor structure of the present invention, the substrate includes a memory region, a periphery region and a peripheral device region, the periphery region is located between the memory region and the edge region, and the through via is located in the memory region.

The manufacturing method of a semiconductor structure for a 3D memory of the present invention includes the following steps. A dielectric layer is formed on a substrate. A ground layer is formed on the dielectric layer. A ground via electrically connected to the substrate is formed in the ground layer and the dielectric layer. A dielectric stacked structure is formed on the ground layer. A through via connected to the ground layer is formed in the dielectric stacked structure. A patterned hard mask layer is formed on the dielectric stacked structure, wherein the patterned hard mask layer is extended onto a sidewall of the dielectric stacked structure. A vertical channel hole is formed in the dielectric stacked structure by using the patterned hard mask layer as a mask.

In an embodiment of the manufacturing method of a semiconductor structure for a 3D memory of the present invention, a bottom surface of the through via is located on a top surface of the ground layer.

In an embodiment of the manufacturing method of a semiconductor structure for a 3D memory of the present invention, a bottom surface of the through via is located in the ground layer.

In an embodiment of the manufacturing method of a semiconductor structure for a 3D memory of the present invention, a bottom surface of the through via is located on a top surface of the dielectric layer.

In an embodiment of the manufacturing method of a semiconductor structure for a 3D memory of the present invention, the manufacturing method further includes forming a device structure layer on the substrate before forming the dielectric layer.

In an embodiment of the manufacturing method of a semiconductor structure for a 3D memory of the present invention, the substrate comprises a memory region, a periphery region, an edge region and a peripheral device region, the periphery region is located between the memory region and the edge region, the peripheral device region is adjacent to the memory region, and the device structure layer is formed on the substrate in the peripheral device region.

In an embodiment of the manufacturing method of a semiconductor structure for a 3D memory of the present invention, a thickness of the patterned hard mask layer on a top surface of the dielectric stacked structure is greater than a thickness of the patterned hard mask layer on the sidewall of the dielectric stacked structure.

Based on the above, in the semiconductor structure for a 3D memory in the present invention, the through via is disposed in the dielectric stacked structure and connected to the ground layer, and the ground layer is electrically connected to the substrate through the ground via. Therefore, a conductive path composed of the through via, the ground layer and the ground via may be formed, and the charges generated in the process may be transmitted to the substrate through the conductive path. In this way, the arcing caused by the charge accumulation may be effectively prevented, thereby preventing the substrate and/or the device disposed on the substrate from being damaged by the arcing.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1A to 1E are schematic cross-sectional views of the manufacturing process of the semiconductor structure for a 3D memory of the first embodiment of the present invention.

FIGS. 2A to 2B are schematic cross-sectional views of the manufacturing process of the semiconductor structure for a 3D memory of the second embodiment of the present invention.

FIG. 3 is a schematic cross-sectional view of the through via of another embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

The semiconductor structure of the present invention may be applied in a 3D memory, especially in a 3D flash memory, to prevent arcing in the process, thereby avoiding damage to the substrate and/or the device disposed on the substrate. The semiconductor structure of the present invention will be described in detail below.

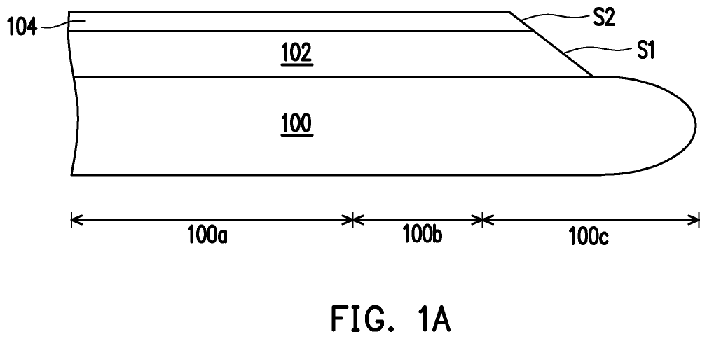

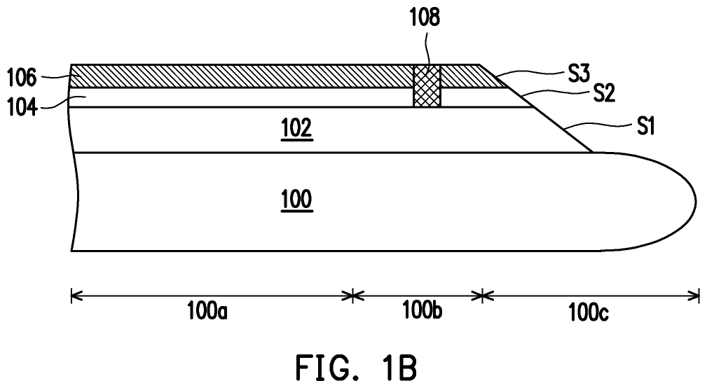

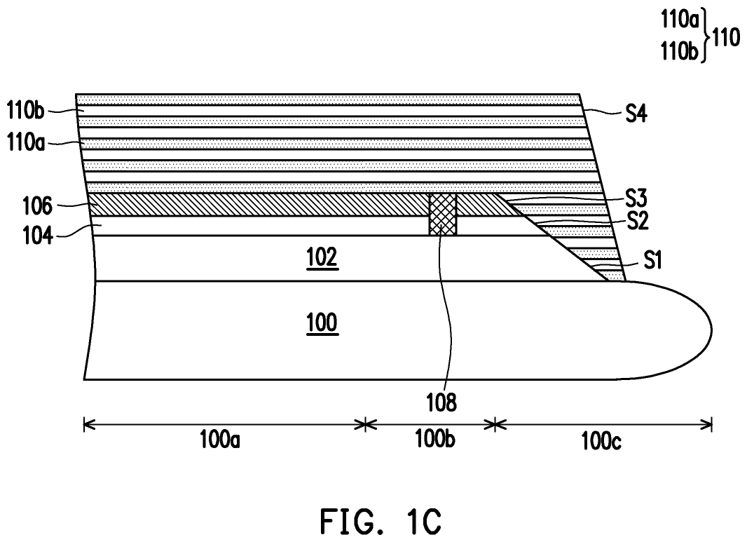

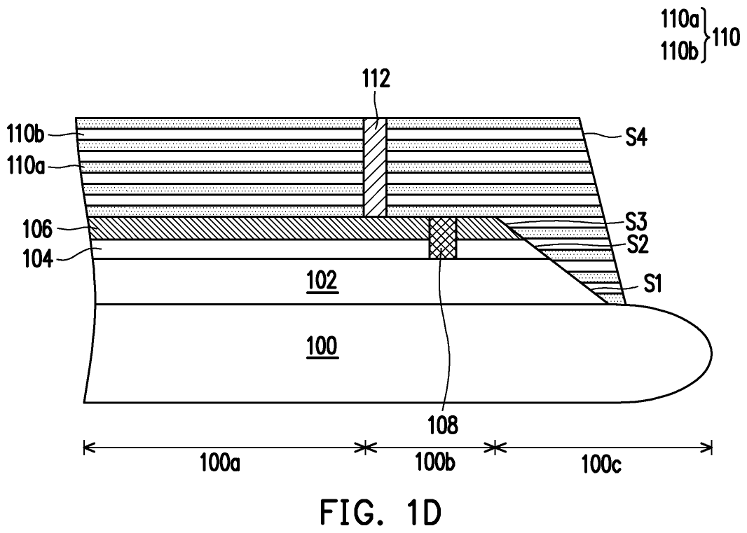

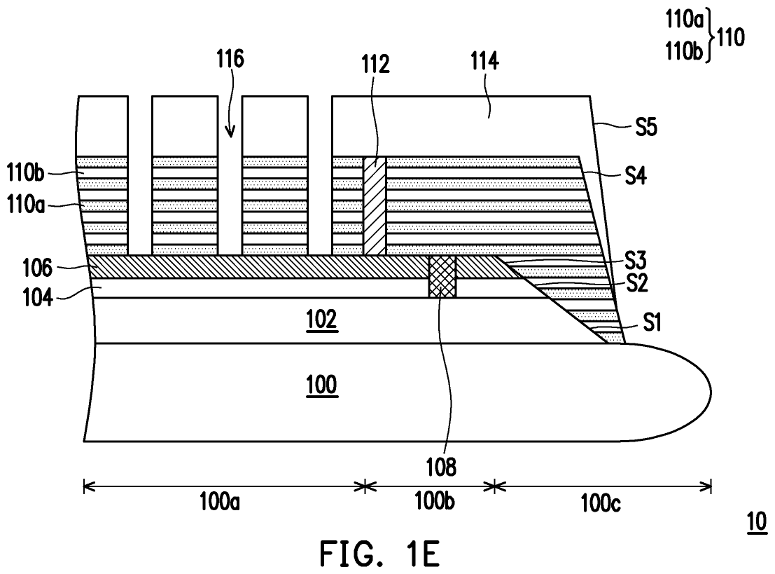

FIGS. 1A to 1E are schematic cross-sectional views of the manufacturing process of the semiconductor structure for a 3D memory of the first embodiment of the present invention.

Referring to FIG. 1A, a substrate 100 is provided. The substrate 100 includes a memory region 100a, a periphery region 100b and an edge region 100c. Generally speaking, after the 3D memory is formed, a staircase structure is formed in the periphery region 100b, so the periphery region 100b may also be called a staircase region. In the present embodiment, the substrate 100 is, for example, a silicon wafer. Then, a device structure layer 102 is formed on the substrate 100. The device structure layer 102 is electrically connected to the substrate 100. To make the drawing clear and easy to describe, the detailed structure of the device structure layer 102 is not shown in FIG. 1A. The device structure layer 102 may include various commonly known semiconductor devices. For example, in the present embodiment, the device structure layer 102 may include the metal oxide semiconductor (MOS) transistor formed at the surface of the substrate 100, the interconnect structure electrically connected to the MOS transistor and the dielectric layer covering the MOS transistor and the interconnect structure, but the present invention is not limited thereto. In other embodiments, the device structure layer 102 may further include other semiconductor devices well known to those skilled in the art. In addition, the method for forming the device structure layer 102 is well known to those skilled in the art, and will not be further described here.

Usually, the edge of the substrate has a beveled profile, so that the film layer formed at the edge of the substrate may have a beveled sidewall. Therefore, in the present embodiment, the device structure layer 102 formed adjacent to the edge of the substrate 100 has a beveled sidewall S1.

Then, a dielectric layer 104 is formed on the device structure layer 102. The dielectric layer 104 may be used as an insulating layer between the subsequently formed conductive layer and the device structure layer 102. In the present embodiment, the dielectric layer 104 is a silicon oxide layer, but the present invention is not limited thereto. The method for forming the dielectric layer 104 is well known to those skilled in the art, and will not be further described here. Likewise, the dielectric layer 104 formed adjacent to the edge of the substrate 100 has a beveled sidewall S2.

Referring to FIG. 1B, a ground layer 106 is formed on the dielectric layer 104. The ground layer 106 may be used to transmit charges generated in subsequent processes to the substrate 100. In the present embodiment, the ground layer 106 is a polysilicon layer, but the present invention is not limited thereto. In other embodiments, the ground layer 106 may be another conductive layer, such as a metal layer. Likewise, the ground layer 106 formed adjacent to the edge of the substrate 100 has a beveled sidewall S3.

After that, a ground via 108 is formed in the ground layer 106 and the dielectric layer 104. A method for forming the ground via 108 may include the following steps. A hole exposing a conductive pad of the device structure layer 102 is formed in the ground layer 106 and the dielectric layer 104. Then, the hole is filled with a conductive material. In the present embodiment, a material of the ground via 108 may be tungsten (W). In this way, the ground via 108 may connect the ground layer 106 and the conductive pad in the device structure layer 102, so that the ground layer 106 may be electrically connected to the device structure layer 102. In FIG. 1C, only one ground via 108 is shown, and the ground via 108 is adjacent to the edge of the substrate 100, but the present invention is not limited thereto. In other embodiments, a plurality of ground via 108 may be formed in the ground layer 106 and the dielectric layer 104 depending on the actual situation, and the ground via(s) 108 may be located in any suitable position(s). In the present embodiment, the ground via 108 is located in the periphery region 100b.

Referring to FIG. 1C, a dielectric stacked structure 110 is formed on the ground layer 106. The dielectric stacked structure 110 is formed by alternately stacking different dielectric layers. The dielectric stacked structure 110 serves as an initial structure for subsequently forming of a 3D memory, which is well known to those skilled in the art and will not be further described here. In the present embodiment, the dielectric stacked structure 110 includes a plurality of oxide layer 110a and a plurality of nitride layer 110b, and the oxide layers 110a and the nitride layers 110b are formed alternately on the ground layer 106. The nitride layer 110b may be used as a sacrificial layer for forming a gate of a memory. The method for forming the dielectric stacked structure 110 is well known to those skilled in the art, and will not be further described here. In addition, in the present embodiment, a part of the dielectric stacked structure 110 is located on the substrate 100. That is, the dielectric stacked structure 110 covers the device structure layer 102, the dielectric layer 104 and the ground layer 106. Likewise, the dielectric stacked structure 110 formed adjacent to the edge of the substrate 100 has a beveled sidewall S4.

Referring to FIG. 1D, a through via 112 connected to the ground layer 106 is formed in the dielectric stacked structure 110. A method for forming the through via 112 may include the following steps. A hole exposing the ground layer 106 is formed in the dielectric stacked structure 110 and the ground layer 106. Then, the hole is filled with a conductive material. In the present embodiment, a material of through via 112 may be polysilicon or metal. In the present embodiments, the bottom surface of the through via 112 may be located on the top surface of the ground layer 106. That is, during forming the through via 112, the ground layer 106 is used as an etching stop layer. Alternatively, in other embodiments, the bottom surface of the through via 112 may be located in the ground layer 106, as long as the through via 112 may contact the ground layer 106 to achieve the purpose of electrical connection. Alternatively, in other embodiments, the through via 112 may penetrate through the ground layer 106 such that the bottom surface of the through via 112 is located on the top surface of the dielectric layer 104.

In FIG. 1D, only one through via 112 is shown, and the through via 112 is adjacent to the ground via 108. The shortest distance between the through via 112 and the ground via 108 is, for example, 10% or more of the aperture of the ground via 108. In other embodiments, a plurality of through via 112 may be formed, and the through via(s) 112 may be formed in other position(s) in the dielectric stacked structure 110 depending on the actual situation, which is not limited by the present invention.

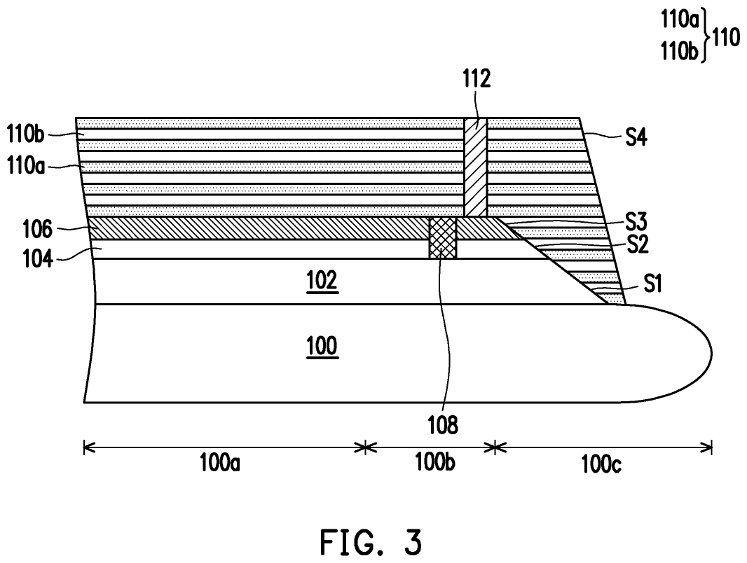

In the present embodiments, the through via 112 is located in the periphery region 100b and between the ground via 108 and the memory region 100a, but the present invention is not limited thereto. In other embodiments, as shown in FIG. 3, the through via 112 may be located in the periphery region 100b and between the ground via 108 and the edge region 100c.

Referring to FIG. 1E, a patterned hard mask layer 114 is formed on the dielectric stacked structure 110. The patterned hard mask layer 114 has openings exposing regions where the vertical channel holes of a 3D memory are to be formed. In addition, since the dielectric stacked structure 110 adjacent to the edge of the substrate 100 has the beveled sidewall S4, the patterned hard mask layer 114 formed on the dielectric stacked structure 110 may be extended onto the sidewall S4 of the dielectric stacked structure 110 and have a beveled sidewall S5. In this way, the thickness of the patterned hard mask layer 114 on the top surface of the dielectric stacked structure 110 is greater than the thickness of the patterned hard mask layer 114 on the sidewall S4 of the dielectric stacked structure 110.

Afterwards, an etching process is performed by using the patterned hard mask layer 114 as an etching mask to remove a part of the dielectric stacked structure 110 to form vertical channel holes 116 exposing the ground layer 106 in the dielectric stacked structure 110. In the present embodiment, the depth of the vertical channel hole 116 is the same as the depth of the through via 112. That is, the bottom surface of the through via 112 and the bottom surface of the vertical channel hole 116 are located at the same level, but the present invention is not limited thereto.

The aperture of the through via 112 may be the same as the aperture of the vertical channel hole 116, but the present invention is not limited thereto. In addition, the shortest distance between the through via 112 and the vertical channel hole 116 is, for example, 10% or more of the aperture of the vertical channel hole 116, so as to prevent the through via 112 from being too close to the vertical channel hole 116 to affect the channel region of the subsequently formed memory.

In this way, the semiconductor structure 10 of the present embodiment is completed. Subsequently, a well-known 3D memory process may be performed on the semiconductor structure 10 to form a 3D memory.

In semiconductor structure 10, the through via 112 is disposed in dielectric stacked structure 110 and connected to the ground layer 106, and the ground layer 106 is electrically connected to the device structure layer 102 disposed on substrate 100 through the ground via 108. Therefore, a conductive path composed of the through via 112, the ground layer 106, the ground via 108 and a conductive device in the device structure layer 102 is formed in the semiconductor structure 10. Therefore, even though the thickness of the patterned hard mask layer 114 on the sidewall of the dielectric stacked structure 110 is thinner, the charges generated during the formation of the vertical channel holes 116 using a dry etching process may be transmitted to the substrate 100 through the conductive path without accumulating around the vertical channel holes 116 and at the thinner portion of the patterned hard mask layer 114. Therefore, the arcing during the process may be effectively prevented to avoid damage to the substrate and/or the device disposed on the substrate.

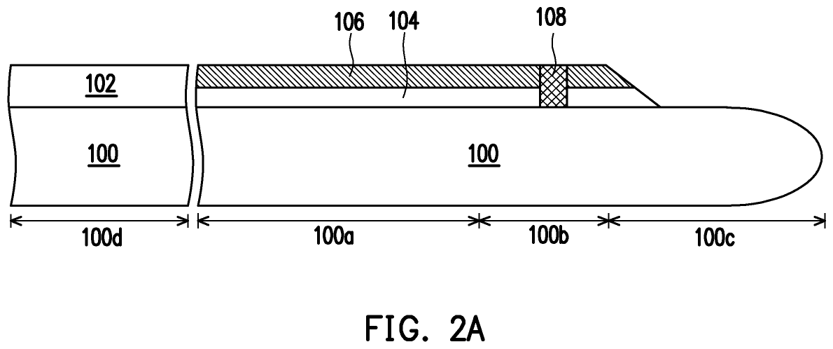

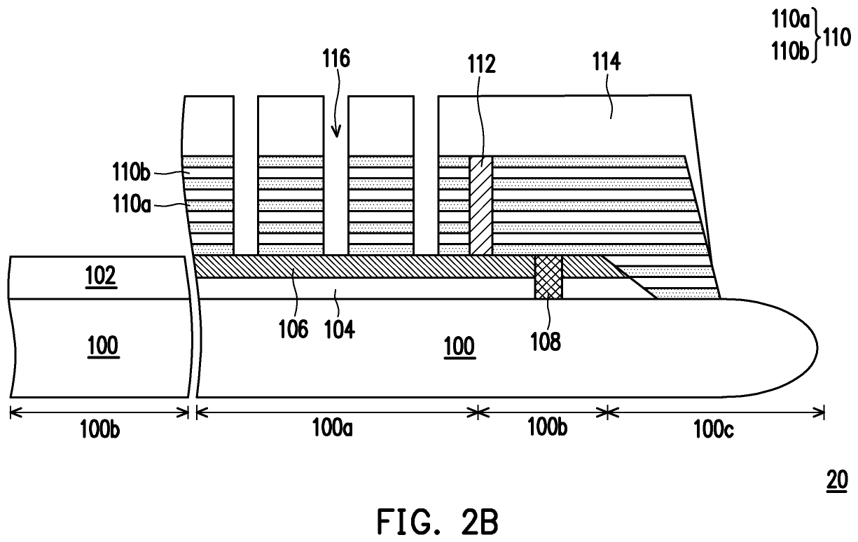

FIGS. 2A to 2B are schematic cross-sectional views of the manufacturing process of the semiconductor structure for a 3D memory of the second embodiment of the present invention. In the present embodiment, the same device as that of the first embodiment will be denoted by the same reference number and will not be described again.

Referring to FIG. 2A, in the present embodiment, the substrate 100 has a memory region 100a, a periphery region 100b, an edge region 100c and a peripheral device region 100d. The peripheral device region 100d is adjacent to the memory region 100a. The device structure layer 102 is formed on the substrate 100 in the peripheral device region 100d. Then, the dielectric layer 104 and the ground layer 106 are formed on the substrate 100 in the memory region 100a, a periphery region 100b and an edge region 100c. Next, the ground via 108 connected to the substrate 100 is formed in the dielectric layer 104 and the ground layer 106. That is, in the present embodiment, the device structure layer 102 including the MOS transistor, the interconnect structure and the dielectric layer covering the MOS transistor and the interconnect structure is not formed under a subsequently formed 3D memory, but is formed outside the memory region 100a.

Referring to FIG. 2B, the steps described in FIG. 1C to FIG. 1E are performed to form a semiconductor structure 20. In semiconductor structure 20, the through via 112 is disposed in dielectric stacked structure 110 and connected to the ground layer 106, and the ground via 108 penetrates through dielectric layer 104 and is connected to substrate 100. Therefore, a conductive path composed of the through via 112, the ground layer 106 and the ground via 108 is formed in the semiconductor structure 20. Therefore, even though the thickness of the patterned hard mask layer 114 on the sidewall of the dielectric stacked structure 110 is thinner, the charges generated during the formation of the vertical channel holes 116 using a dry etching process may be transmitted to the substrate 100 through the conductive path without accumulating around the vertical channel holes 116 and at the thinner portion of the patterned hard mask layer 114. Therefore, the arcing during the process may be effectively prevented to avoid damage to the substrate and/or the device disposed on the substrate.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure for a three-dimensional (3D) memory, comprising:
a dielectric layer, disposed on a substrate;
a ground layer, disposed on the dielectric layer;
a ground via, disposed in the ground layer and the dielectric layer, and electrically connected to the substrate;
a dielectric stacked structure, disposed on the ground layer; and
a through via, disposed in the dielectric stacked structure, and connected to the ground layer,
wherein the dielectric stacked structure has a vertical channel hole.

2. The semiconductor structure for a 3D memory of claim 1, wherein a material of the through via comprises polysilicon or metal.

3. The semiconductor structure for a 3D memory of claim 1, wherein an aperture of the through via is the same as an aperture of the vertical channel hole.

4. The semiconductor structure for a 3D memory of claim 1, wherein a shortest distance between the through via and the vertical channel hole is 10% or more of an aperture of the vertical channel hole.

5. The semiconductor structure for a 3D memory of claim 1, wherein a shortest distance between the through via and the ground via is 10% or more of an aperture of the ground via.

6. The semiconductor structure for a 3D memory of claim 1, wherein a bottom surface of the through via is located on a top surface of the ground layer.

7. The semiconductor structure for a 3D memory of claim 1, wherein a bottom surface of the through via is located in the ground layer.

8. The semiconductor structure for a 3D memory of claim 1, wherein a bottom surface of the through via is located on a top surface of the dielectric layer.

9. The semiconductor structure for a 3D memory of claim 1, wherein a bottom surface of the through via is located at the same level as a bottom surface of the vertical channel hole.

10. The semiconductor structure for a 3D memory of claim 1, further comprising a device structure layer disposed between the substrate and the dielectric layer, wherein the ground via is electrically connected to the substrate through the device structure layer.

11. The semiconductor structure for a 3D memory of claim 1, further including a device structure layer, wherein the substrate comprises a memory region, a periphery region, an edge region and a peripheral device region, the periphery region is located between the memory region and the edge region, the peripheral device region is adjacent to the memory region, and the device structure layer is disposed on the substrate in the peripheral device region.

12. The semiconductor structure for a 3D memory of claim 1, wherein the substrate comprises a memory region, a periphery region and a peripheral device region, the periphery region is located between the memory region and the edge region, and the through via is located in the periphery region.

13. The semiconductor structure for a 3D memory of claim 1, wherein the substrate comprises a memory region, a periphery region and a peripheral device region, the periphery region is located between the memory region and the edge region, and the through via is located in the memory region.

14. A manufacturing method of a semiconductor structure for a 3D memory, comprising:
forming a dielectric layer on a substrate;
forming a ground layer on the dielectric layer;
forming a ground via electrically connected to the substrate in the ground layer and the dielectric layer;
forming a dielectric stacked structure on the ground layer;
forming a through via connected to the ground layer in the dielectric stacked structure;
forming a patterned hard mask layer on the dielectric stacked structure, wherein the patterned hard mask layer is extended onto a sidewall of the dielectric stacked structure; and
forming a vertical channel hole in the dielectric stacked structure by using the patterned hard mask layer as a mask.

15. The manufacturing method of claim 14, wherein a bottom surface of the through via is located on a top surface of the ground layer.

16. The manufacturing method of claim 14, wherein a bottom surface of the through via is located in the ground layer.

17. The manufacturing method of claim 14, wherein a bottom surface of the through via is located on a top surface of the dielectric layer.

18. The manufacturing method of claim 14, further comprising forming a device structure layer on the substrate before forming the dielectric layer.

19. The manufacturing method of claim 18, wherein the substrate comprises a memory region, a periphery region, an edge region and a peripheral device region, the periphery region is located between the memory region and the edge region, the peripheral device region is adjacent to the memory region, and the device structure layer is formed on the substrate in the peripheral device region.

20. The manufacturing method of claim 14, wherein a thickness of the patterned hard mask layer on a top surface of the dielectric stacked structure is greater than a thickness of the patterned hard mask layer on the sidewall of the dielectric stacked structure.
